(19) United States
(12) Patent Application Publication
(10) Pub. No.: US 2024/0363510 A1
(43) Pub. Date: Oct. 31, 2024

(54) CHIP ON FILM, METHOD FOR MANUFACTURING THE SAME, AND DISPLAY DEVICE

(71) Applicant: BOE Technology Group Co., Ltd., Beijing (CN)

(72) Inventors: Liuqing Li, Beijing (CN); Shuilang Dong, Beijing (CN); Xinhong Lu, Beijing (CN); Guoteng Li, Beijing (CN); Jingshang Zhou, Beijing (CN); Baoman Li, Beijing (CN)

(21) Appl. No.: 18/580,229

(22) PCT Filed: Nov. 24, 2022
(86) PCT No.: PCT/CN2022/133873

§ 371 Date: Jan. 18, 2024

(51) Int. Cl. H01L 23/498; H01L 21/48

(52) U.S. Cl. CPC H01L 23/49822; H01L 21/4857; H01L 23/4985

(57) ABSTRACT

A chip on film includes: a flexible substrate; and a multilayer wiring structure disposed on the flexible substrate. The multilayer wiring structure includes a first wiring layer, a first insulation layer and a second wiring layer, which are sequentially arranged in a direction towards the flexible substrate the flexible substrate. The first wiring layer includes a first conductive material and the second wiring layer includes a second conductive material. The chip on film further includes: pins, at least part of which are in the first wiring layer; first via holes in the first insulation layer; and a second wire and a second wire leading portion in the second wiring layer, which are electrically connected to each other. More than one pin is electrically connected to the second wire leading portion through more than one first via hole, respectively.

### CROSS-REFERENCE TO RELATED APPLICATION

This application is a Section 371 National Stage Application of International Application No. PCT/CN2022/133873, filed Nov. 24, 2022, entitled “CHIP ON FILM, METHOD FOR MANUFACTURING THE SAME, AND DISPLAY DEVICE”, the content of which is incorporated herein by reference in its entirety.

### TECHNICAL FIELD

The present disclosure relates to a field of display technology, and in particular, to a chip on film, a method for manufacturing the same, and a display device.

### BACKGROUND

In current semiconductor devices such as display devices, generally, various types of integrated circuits (IC) are required, including but not limited to a driver IC, a touch IC, and an ROIC, etc. The encapsulation and bonding for these chips may be implemented by using chip encapsulation techniques such as COF (the abbreviation of Chip On Film). With a development of high-resolution 3D display products, multi-channel COF driving becomes a future trend. Accordingly, COF encapsulation products with higher resolution are required.

The above information disclosed in this section is only for understanding the background of the technical concept of the present disclosure. Therefore, the above information may include information that does not constitute the existing technologies.

### SUMMARY

In order to solve at least one aspect of the above problems, embodiments of the present disclosure provide a chip on film, a method for manufacturing the same, and a display device.

In an aspect, a chip on film is provided, including: a flexible substrate: and a multilayer wiring structure disposed on the flexible substrate. The multilayer wiring structure includes: a first wiring layer disposed on the flexible substrate, where the first wiring layer includes a first conductive material; a first insulation layer disposed on a side of the first wiring layer close to the flexible substrate; and a second wiring layer disposed on a side of the first insulation layer close to the flexible substrate, where the second wiring layer includes a second conductive material. The chip on film further includes: a plurality of pins, at least part of which is located in the first wiring layer; a plurality of first via holes in the first insulation layer; and a second wire and a second wire leading portion which are in the second wiring layer, where the second wire is electrically connected to the second wire leading portion, and more than one pin is electrically connected to the second wire leading portion through more than one first via hole, respectively. The chip on film further includes an adhesive overflow space between at least two adjacent pins among the plurality of pins, the first insulation layer includes a first insulation surface away from the flexible substrate, the first insulation surface includes a first insulation surface portion and a second insulation surface portion, an orthographic projection of the first insulation surface portion on the flexible substrate at least partially overlaps with an orthographic projection of more than one pin on the flexible substrate, an orthographic projection of the second insulation surface portion on the flexible substrate at least partially overlaps with an orthographic projection of the adhesive overflow space on the flexible substrate, at least part of a surface of the more than one pin close to the flexible substrate is in contact with the first insulation surface portion, at least part of the second insulation surface portion serves as a bottom surface of the adhesive overflow space, and the first insulation surface portion and the second insulation surface portion are in a same plane. The plurality of pins have substantially a same thickness in a first direction, where the first direction is a direction perpendicular to the first surface of the flexible substrate.

According to some exemplary embodiments, the flexible substrate includes a first surface, and the first surface of the flexible substrate is a surface of the flexible substrate close to the first wiring layer.

According to some exemplary embodiments, two side surfaces of the at least two adjacent pins among the plurality of pins serve as side surfaces of the adhesive overflow space, where the two side surfaces opposite to each other.

According to some exemplary embodiments, the chip on film further includes a first wire in the first wiring layer, the first wire is electrically connected to part of the plurality of pins, and thicknesses of the plurality of pins in the first direction are greater than a thickness of the first wire in the first direction.

According to some exemplary embodiments, the thicknesses of the plurality of pins in the first direction are greater than a thickness of the second wire in the first direction or a thickness of the second wire leading potion in the first direction.

According to some exemplary embodiments, the chip on film further includes: a second insulation layer disposed on a side of the second wiring layer close to the flexible substrate; and a third wiring layer disposed on a side of the second insulation layer close to the flexible substrate, where the third wiring layer includes a third conductive material. The chip on film further includes: a plurality of second via holes in the second insulation layer; a transition portion in the second wiring layer; and a third wire and a third wire leading portion which are in the third wiring layer. The third wire is electrically connected to the third wire leading portion. Part of the plurality of pins are electrically connected to the transition portion through more than one first via hole, respectively, and the transition portion is electrically connected to the third wire leading portion through more than one second via hole.

According to some exemplary embodiments, the chip on film further includes an anti-oxidation layer on a side of the first wiring layer away from the flexible substrate, and at least one anti-oxidation portion in the anti-oxidation layer covers at least one pin.

According to some exemplary embodiments, the chip on film further includes an anti-oxidation layer on a side of the first wiring layer away from the flexible substrate, where a material of the anti-oxidation layer includes a gold nickel alloy, at least one pin includes a first sub-pin in the first wiring layer and a second sub-pin in the anti-oxidation layer, and for a same pin, the second sub-pin covers the first sub-pin.

According to some exemplary embodiments, in the first direction, a thickness of the second sub-pin is greater than a thickness of the first sub-pin covered by the second sub-pin.

According to some exemplary embodiments, the chip on film further includes a first height adjustment layer between the first wiring layer and the first insulation layer, where at least one pin includes a first pin in the first wiring layer and a first height adjustment portion in the first height adjustment layer, and for a same pin, an orthographic projection of the first pin on the flexible substrate falls within an orthographic projection of the first height adjustment portion on the flexible substrate.

According to some exemplary embodiments, a material of the first height adjustment layer is different from a material of the first insulation layer, and the material of the first height adjustment layer is different from a material of the first wiring layer.

According to some exemplary embodiments, the chip on film further includes: a first height adjustment layer on a side of the first wiring layer away from the flexible substrate; and a second height adjustment layer on a side of the first height adjustment layer away from the flexible substrate. At least one pin includes: a first pin in the first wiring layer; a first height adjustment portion in the first height adjustment layer; and a second height adjustment portion in the second height adjustment layer, where for a same pin, an orthographic projection of the second height adjustment portion on the flexible substrate falls within an orthographic projection of the first height adjustment portion on the flexible substrate, and the orthographic projection of the first height adjustment portion on the flexible substrate falls within an orthographic projection of the first pin on the flexible substrate.

According to some exemplary embodiments, a material of the first height adjustment layer is different from a material of the first wiring layer, and the material of the first height adjustment layer is different from a material of the second height adjustment layer.

According to some exemplary embodiments, each of the first conductive material and the second conductive material includes copper.

According to some exemplary embodiments, each of the first conductive material, the second conductive material and the third conductive material includes copper.

According to some exemplary embodiments, the first insulation layer includes a first inorganic insulation layer and a first planarization layer, the first inorganic insulation layer is between the first wiring layer and the first planarization layer, and the first insulation surface is a surface of the first inorganic insulation layer away from the flexible substrate.

According to some exemplary embodiments, in the first direction, a thickness of the first wire is equal to a thickness of the second wire.

According to some exemplary embodiments, orthographic projections of the plurality of pins on the flexible substrate are arranged in an array, and orthographic projections of part of the plurality of pins on the flexible substrate at least partially overlaps with an orthographic projection of the second wire leading portion on the flexible substrate.

According to some exemplary embodiments, the second height adjustment layer includes a conductive material, and the second height adjustment portion is electrically connected to the first pin through a third via hole penetrating the first height adjustment portion.

According to some exemplary embodiments, a thickness of the first height adjustment portion in the first direction is more than 2 μm.

According to some exemplary embodiments, a thickness of the first height adjustment portion in the first direction is more than 2 μm; and/or, a thickness of the second height adjustment portion in the first direction is more than 2 μm.

In another aspect, a display device is provided, including a display panel, a circuit board, and the chip on film as described above. The display panel is electrically connected to the circuit board through the chip on film.

In yet another aspect, a method for manufacturing a chip on film is provided, including:
forming a second wiring layer on a flexible substrate, where the second wiring layer includes a second conductive material;
forming, by using a patterning process, a second wire and a second wire leading portion in the second wiring layer, where the second wire is electrically connected to the second wire leading portion;
forming a first insulation layer on a side of the second wiring layer away from the flexible substrate;
forming a plurality of first via holes in the first insulation layer;
forming a first wiring layer on a side of the first insulation layer away from the flexible substrate, where the first wiring layer includes a first conductive material; and
forming a plurality of pins in the first wiring layer, so that more than one pin is electrically connected to the second wire leading portion through more than one first via hole, respectively,
where the chip on film further includes an adhesive overflow space between at least two adjacent pins among the plurality of pins, the first insulation layer includes a first insulation surface away from the flexible substrate, the first insulation surface includes a first insulation surface portion and a second insulation surface portion, an orthographic projection of the first insulation surface portion on the flexible substrate at least partially overlaps with an orthographic projection of more than one pin on the flexible substrate, an orthographic projection of the second insulation surface portion on the flexible substrate at least partially overlaps with an orthographic projection of the adhesive overflow space on the flexible substrate, at least part of a surface of the more than one pin close to the flexible substrate is in contact with the first insulation surface portion, at least part of the second insulation surface portion serves as a bottom surface of the adhesive overflow space, and the first insulation surface portion and the second insulation surface portion are in a same plane.

According to some exemplary embodiments, the first conductive material includes copper, and the forming a first wiring layer on a side of the first insulation layer away from the flexible substrate includes: forming a copper seed layer on the side of the first insulation layer away from the flexible substrate; and electroplating a copper layer on a surface of the copper seed layer away from the flexible substrate, so as to form the first wiring layer including the copper seed layer and the copper layer.

According to some exemplary embodiments, the forming a plurality of pins in the first wiring layer includes:
performing a patterning process on the first wiring layer including the copper seed layer and the copper layer to form a first sub-pin; and
performing an electroless nickel immersion gold process on the first sub-pin to form a second sub-pin covering the first sub-pin.

According to some exemplary embodiments, before forming the first wiring layer, the method further includes: forming a first height adjustment layer on a side of the first insulation layer away from the flexible substrate; and performing a patterning process on the first height adjustment layer to form a first height adjustment portion in the first height adjustment layer. The forming a plurality of pins in the first wiring layer includes: performing a dry etching process on the first wiring layer to form a first pin, so that at least one of the plurality of pins includes the first pin in the first wiring layer and the first height adjustment portion in the first height adjustment layer, where for a same pin, an orthographic projection of the first pin on the flexible substrate falls within an orthographic projection of the first height adjustment portion on the flexible substrate.

According to some exemplary embodiments, the forming a plurality of pins in the first wiring layer includes:
performing a dry etching process on the first wiring layer to form a first pin;
forming a first height adjustment layer on a side of the first pin away from the flexible substrate, and performing a patterning process on the first height adjustment layer, so as to form a first height adjustment portion and a third via hole penetrating the first height adjustment portion; and
forming a second height adjustment layer on a side of the first height adjustment portion away from the flexible substrate, and performing a patterning process on the second height adjustment layer, so as to form a second height adjustment portion,
where for a same pin, an orthographic projection of the second height adjustment portion on the flexible substrate falls within an orthographic projection of the first height adjustment portion on the flexible substrate, and the orthographic projection of the first height adjustment portion on the flexible substrate falls within an orthographic projection of the first pin on the flexible substrate.

### BRIEF DESCRIPTION OF THE DRAWINGS

Through the following descriptions of the present disclosure with reference to the accompanying drawings, other objectives and advantages of the present disclosure will become more apparent, and may contribute to a comprehensive understanding of the present disclosure.

FIG. 1 shows a schematic diagram of a display device according to an embodiment of the present disclosure;

FIG. 2 shows a schematic diagram of a display panel according to an embodiment of the present disclosure;

FIG. 3 shows a schematic top view of a chip on film according to some embodiments of the present disclosure;

FIG. 4 shows a schematic top view of a chip on film according to some other embodiments of the present disclosure;

FIG. 5A is a schematic diagram schematically showing a planar structure of a multilayer wiring structure included in a chip on film according to an embodiment of the present disclosure;

FIG. 5B is a schematic diagram schematically showing a sectional structure of a multilayer wiring structure included in a chip on film according to embodiments of the present disclosure;

FIG. 6A is a schematic diagram schematically showing a planar structure of a multilayer wiring structure included in a chip on film according to some other embodiments of the present disclosure;

FIG. 6B is a schematic diagram schematically showing a sectional structure of a multilayer wiring structure included in a chip on film according to some other embodiments of the present disclosure;

FIG. 7 shows a schematic diagram of a chip on film according to some other embodiments of the present disclosure, where a pin of the chip on film includes a portion formed by an electroless nickel immersion gold process;

FIG. 8 shows a schematic diagram of a chip on film according to some other embodiments of the present disclosure, where a pin of the chip on film includes one height adjustment portion;

FIG. 9 shows a schematic diagram of a chip on film according to some other embodiments of the present disclosure, where a pin of the chip on film includes two height adjustment portions;

FIG. 10 shows a flowchart of a method for manufacturing a chip on film according to an embodiment of the present disclosure;

FIG. 11A to FIG. 11J show schematic diagrams of structures formed after some steps of a method for manufacturing a chip on film according to an embodiment of the present disclosure are performed, where two layers of wires are formed;

FIG. 12A to FIG. 12E show schematic diagrams of structures formed after some steps of a method for manufacturing a chip on film according to an embodiment of the present disclosure are performed, where three layers of wires are formed;

FIG. 13A to FIG. 13B show schematic diagrams of structures formed after some steps of a method for manufacturing a chip on film according to an embodiment of the present disclosure are performed, where a subtractive method and an electroless nickel immersion gold process are adopted;

FIG. 14A to FIG. 14D show schematic diagrams of structures formed after some steps of a method for manufacturing a chip on film according to an embodiment of the present disclosure are performed, where the structure of the chip on film shown in FIG. 8 is formed;

FIG. 15A to FIG. 15D show schematic diagrams of structures formed after some steps of a method for manufacturing a chip on film according to an embodiment of the present disclosure are performed, where the structure of the chip on film shown in FIG. 9 is formed;

FIG. 16 is a schematic diagram schematically showing a planar structure of a single layer wiring structure included in a chip on film in related art; and

FIG. 17 shows a schematic diagram schematically showing a sectional structure of a chip on film in related art.

It should be noted that for the sake of clarity, in the accompanying drawings used to describe the embodiments of the present disclosure, sizes of layers, structures, or regions may be enlarged or reduced, that is, these drawings are not drawn according to actual scales.

### DETAILED DESCRIPTION OF EMBODIMENTS

In the following description, for explanation, many specific details are set forth to provide comprehensive understanding for various exemplary embodiments. However, it is obvious that the various exemplary embodiments may be implemented without these specific details or with one or more equivalent arrangements. In other cases, well-known structures and devices are shown in block diagram form to avoid causing unnecessary ambiguity of the various exemplary embodiments. In addition, the various exemplary embodiments may be different, but need not be exclusive. For example, without departing from the inventive concept, the specific shapes, configurations and features of the exemplary embodiments may be used or implemented in another exemplary embodiment.

In the drawings, for the sake of clarity and/or description, a size and a relative size of an element may be enlarged. In this way, sizes and relative sizes of the various elements are not required to be limited to the sizes and relative sizes shown in the drawings. When the exemplary embodiments may be implemented differently, the specific process sequence may be performed differently from the described sequence. For example, two continuously described processes may be substantially performed simultaneously or in a sequence opposite to the described sequence. In addition, the same reference numerals represent the same elements.

When an element is described as being “on”, “connected to”, or “coupled to” another element, the element may be directly on, directly connected to, or directly coupled to the other element, or intermediate elements may be existed. However, when an element is described as being “directly on”, “directly connected to”, or “directly coupled to” another element, there is no intermediate element existed. Other terms and/or expressions used to describe a relationship between elements should be interpreted in a similar fashion, e.g., “between” versus “directly between”, “adjacent” versus “directly adjacent”, or “on” versus “directly on” etc. Furthermore, the term “connected” may refer to a physical connection, an electrical connection, a communication connection, and/or a fluid connection. In addition, an X axis, a Y axis and a Z axis are not limited to a three axes of a rectangular coordinate system, and may be interpreted in a broader sense. For example, the X, Y, and Z axes may be perpendicular to each other, or may represent different directions that are not perpendicular to each other.

It should be understood that, although the terms first, second, etc. may be used herein to describe various elements, these elements should not be limited by these terms. These terms are only used to distinguish one component from another. For example, without departing from the scope of the example embodiment, a first element may be referred as a second element. Similarly, the second element may be referred as the first element.

In embodiments of the present disclosure, “a plurality of” means two or more, “multiple” means two or more, and “at least one” means one or more, unless otherwise specified.

Herein, the expression “pin” refers to a part of a chip on film electrically connected to other leads, wires, electrodes, etc., including but not limited to a pad of the chip on film.

Herein, the expression “patterning process” refers to a series of process steps for forming a pattern by using steps of photoresist coating, exposure, development, etching, and the like. Herein, unless otherwise specified, the “disposed in the same layer” generally refers to being manufactured by using one patterning process.

Some exemplary embodiments of the present disclosure provide a chip on film, including: a flexible substrate and a multilayer wiring structure disposed on the flexible substrate. The multilayer wiring structure includes: a first wiring layer disposed on the flexible substrate, where the first wiring layer includes a first conductive material; a first insulation layer disposed on a side of the first wiring layer close to the flexible substrate; and a second wiring layer disposed on a side of the first insulation layer close to the flexible substrate, where the second wiring layer includes a second conductive material. The chip on film further includes: a plurality of pins, at least part of which is located in the first wiring layer; a plurality of first via holes in the first insulation layer, and a second wire and a second wire leading portion which are in the second wiring layer. The second wire is electrically connected to the second wire leading portion. More than one pin is electrically connected to the second wire leading portion through more than one first via holes, respectively. The chip on film further includes an adhesive overflow space located between at least two adjacent pins among the plurality of pins. The first insulation layer includes a first insulation surface away from the flexible substrate. The first insulation surface includes a first insulation surface portion and a second insulation surface portion. An orthographic projection of the first insulation surface portion on the flexible substrate at least partially overlaps with an orthographic projection of more than one pin on the flexible substrate. An orthographic projection of the second insulation surface portion on the flexible substrate at least partially overlaps with an orthographic projection of the adhesive overflow space on the flexible substrate. At least part of a surface of the more than one pin close to the flexible substrate is in contact with the first insulation surface portion. At least part of the second insulation surface portion serves as a bottom surface of the adhesive overflow space. The first insulation surface portion and the second insulation surface portion are in a same plane. In the embodiments of the present disclosure, by providing the multilayer wiring structure, it is beneficial to the realization of a high-resolution display device. In addition, through a step difference between a thickness of the pin and a thickness of an adjacent wire, it is beneficial to the provision of a sufficient adhesive overflow space, so as to avoid defects such as short circuit of the wires.

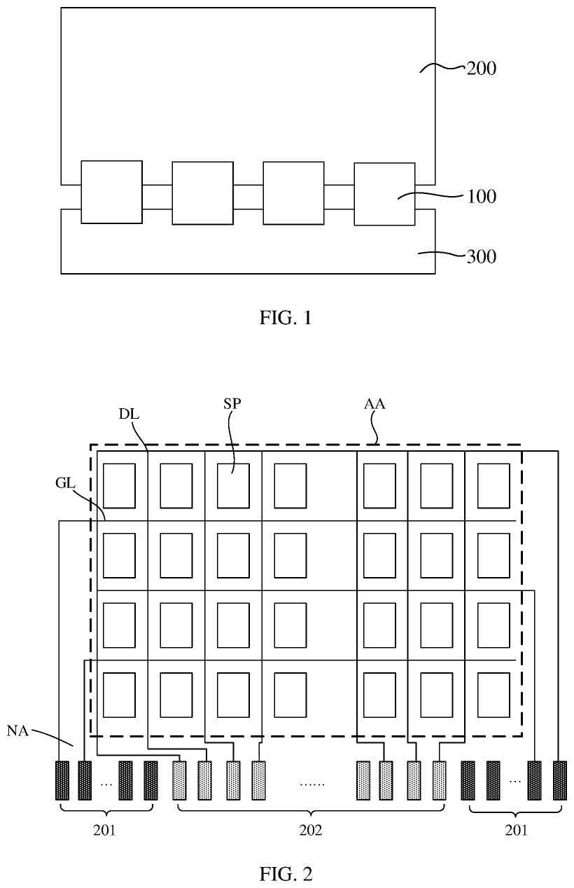

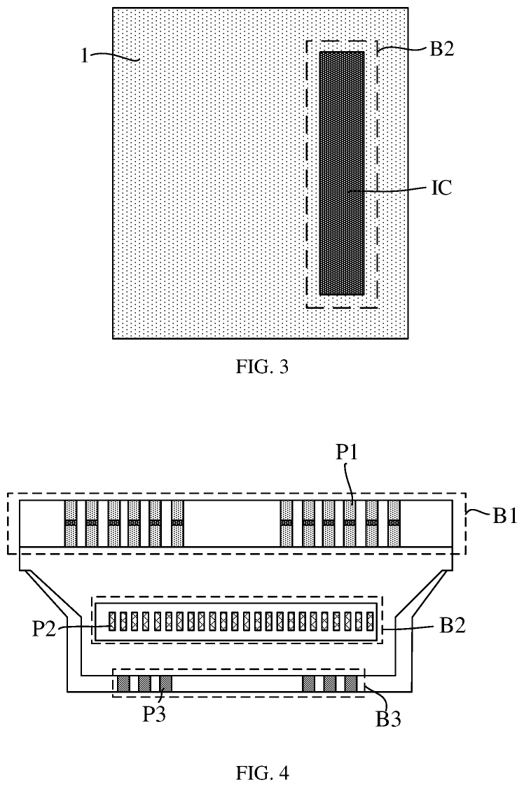

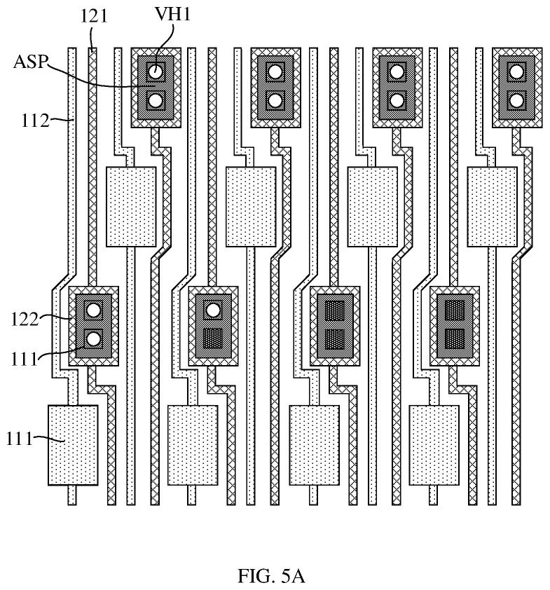

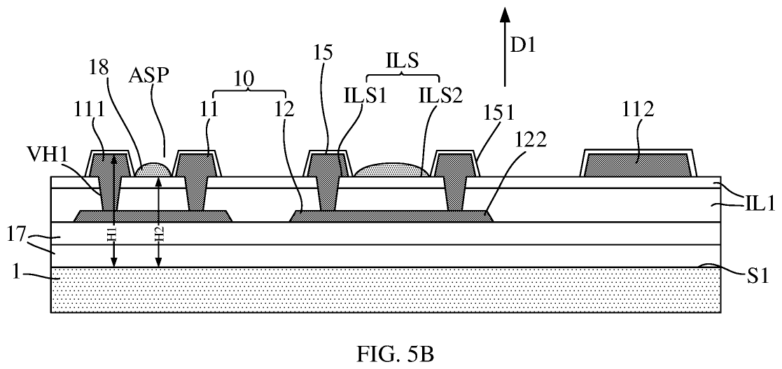

FIG. 1 is a schematic diagram of a display device according to an embodiment of the present disclosure. FIG. 2 is a schematic diagram of a display panel according to an embodiment of the present disclosure. FIG. 3 is a schematic top view of a chip on film according to some embodiments of the present disclosure. FIG. 4 is a schematic top view of a chip on film according to some other embodiments of the present disclosure.

With reference to FIG. 1 to FIG. 4, the display device may include a display panel 200, a chip on film 100 and a circuit board 300. The display panel 200 is electrically connected to the circuit board 300 through the chip on film 100. For example, the display panel 200 may include a display area AA and a peripheral area NA. The peripheral area NA is disposed, for example, around the AA area. In some exemplary embodiments, a plurality of sub-pixels SP may be disposed in the display area.

The plurality of sub-pixels SP mentioned above being arranged in an array is taken as an example in FIG. 2. In this case, the sub-pixels SP arranged in a line along a horizontal direction may be referred to as a same row of sub-pixels. The sub-pixels SP arranged in a line along a vertical direction may be referred to as a same column of sub-pixels. Optionally, the same row of sub-pixels may be connected to a gate line GL, and the same column of sub-pixels may be connected to a data line DL. On this basis, in some embodiments of the present disclosure, as shown in FIG. 2, the display panel 200 may further include a plurality of gate signal input terminals 201 and a plurality of data signal input terminals 202.

As shown in FIG. 2, for a single-side driving display panel, the data signal input terminals 202 and the gate signal input terminals 201 are disposed on a same side of the display panel, where the data signal input terminals 202 are disposed in a middle position, and the gate signal input terminals 201 are disposed at an edge position.

In some embodiments of the present disclosure, the data signal input terminal 202 is electrically connected to the data line DL on the display panel 200, and the gate signal input terminal 201 is electrically connected to the gate line GL.

In this case, both the gate signal input terminal 201 and the data signal input terminal 202 on the display panel 200 may be bonded to the circuit board 300 through the chip on film 100, so as to transmit electrical signals of the circuit board 300 to the display panel 200.

It should be noted that the embodiments of the present disclosure do not specially limit the type of the display panel, and the display panel may be a TN (Twisted Nematic) type liquid crystal display panel, a VA (Vertical Alignment) type liquid crystal display panel, an IPS (In-Plane Switching) type liquid crystal display panel, an ADS (Advanced Super Dimension Switch) type liquid crystal display panel, or the like. Alternatively, the display panel may also be an OLED (Organic Light-Emitting Diode) display panel.

For example, the circuit board 300 may be a FPC (the abbreviation of Flexible Printed Circuit) or PCB (the abbreviation of Printed Circuit Board).

In the embodiments of the present disclosure, a chip on film 100 is provided, as shown in FIG. 3 and FIG. 4, and the chip on film 100 may include a flexible substrate 1.

For example, a material of the flexible substrate 1 may include PI (Polyimide), PA (Polyamide), PBO (Poly-p-phenylene benzobisoxazole), or the like.

In the embodiments of the present disclosure, the chip on film 100 may include a plurality of bonding areas on the flexible substrate 1. For example, with reference to FIG. 3, the plurality of bonding areas may include at least one chip bonding area B2, which is used to be bonded to a chip. Alternatively, the plurality of bonding areas may include a plurality of chip bonding areas B2, which are respectively bonded to a plurality of chips IC. That is to say, in this embodiments, a plurality of chips IC may be disposed on one chip on film 100, and the plurality of chip bonding areas B2 correspond to the plurality of chips IC one by one.

For example, with reference to FIG. 4, the plurality of bonding areas may include a panel bonding area B1, the chip bonding area B2, a circuit board bonding area B3, and other non-bonding areas (other areas not defined by dotted lines in FIG. 4). For example, the panel bonding area B1 is used to be bonded to the display panel 200, the chip bonding area B2 is used to be bonded to the chip, and the circuit board bonding area B3 is used to be bonded to the circuit board 300. In this embodiments, there is no special limitation on the number of the panel bonding area B1, the number of the chip bonding area B2, and the number of the circuit board bonding area B3. For example, a plurality of chip bonding areas B2 may be disposed, so as to be bonded to a plurality of chips IC, respectively.

In the embodiments of the present disclosure, a plurality of pins may be disposed in each bonding area of the chip on film 100. For example, in the panel bonding area B1, a plurality of pins P1 may be disposed to be bonded to corresponding pins of the display panel. In the chip bonding area B2, a plurality of pins P2 may be disposed to be bonded to corresponding pins on the chip IC. In the circuit board bonding area B3, a plurality of pins P3 may be disposed to be bonded to corresponding pins of the circuit board.

In some exemplary embodiments of the present disclosure, since the flexible substrate 1 is made of an organic material and are easily eroded by water oxygen, in order to prevent the water oxygen erosion, the chip on film 100 may further include a water oxygen insulation layer 17, where the water oxygen insulation layer 17 covers the flexible substrate 1, and the wiring layer is disposed on a side of the water oxygen insulation layer 17 away from the flexible substrate 1. It should be noted that a thickness of the water oxygen insulation layer is not specifically limited. For example, the thickness of the water oxygen insulation layer is in a range of 100 nm to 500 nm, and a material of the water oxygen insulation layer may include silicon oxide or silicon nitride.

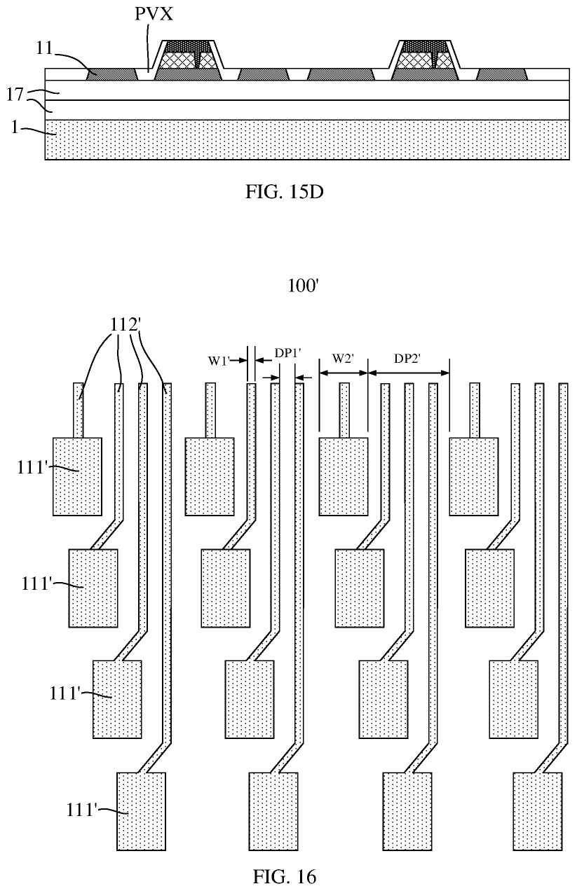

FIG. 16 is a schematic diagram schematically showing a planar structure of a single layer wiring structure included in a chip on film in related art. In the related art, with reference to FIG. 16, a chip on film 100′ includes a single layer wiring structure 10′. In the single layer wiring structure 10′, a plurality of wires 112′ and a plurality of pins 111′ are disposed in a same layer. It should be noted that, as shown in FIG. 16, a wire spacing refers to a sum of a width W1′ of a wire and a spacing DP1′ between adjacent wires. A pin spacing refers to a sum of a width W2′ of a pin and a spacing DP2′ between adjacent pins. At present, a demand for high-resolution display device from users is becoming increasingly strong. In order to achieve high-resolution (such as resolutions above 10K), it is required to increase the number of pins and the number of wires. Accordingly, the wire spacing and the pin spacing will be further decreased, which poses a challenge to the current manufacturing process of the production line for the display device.

In the embodiments of the present disclosure, the chip on film 100 may include a multilayer wiring structure.

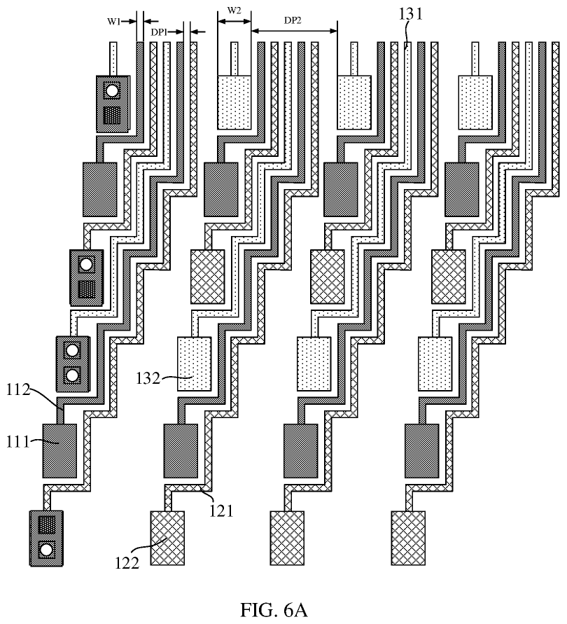

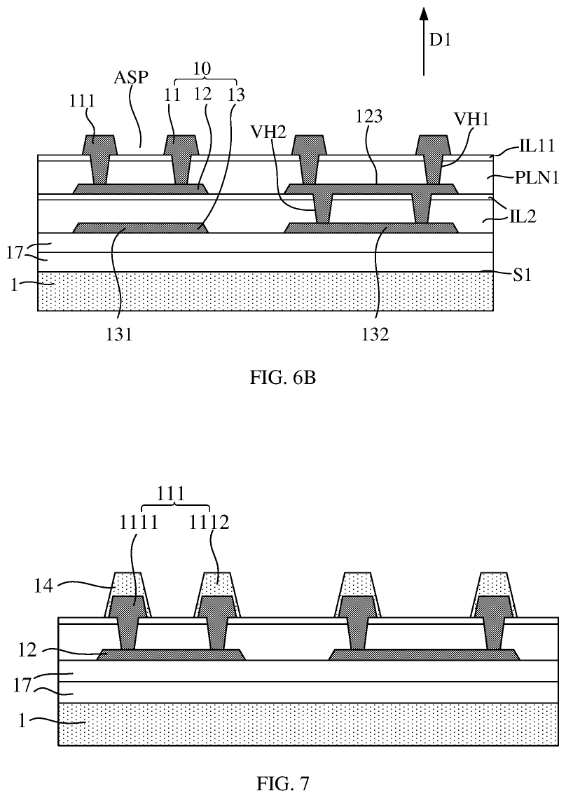

FIG. 5A is a schematic diagram schematically showing a planar structure of a multilayer wiring structure included in a chip on film according to an embodiment of the present disclosure. FIG. 5B is a schematic diagram schematically showing a sectional structure of a multilayer wiring structure included in a chip on film according to an embodiment of the present disclosure. With reference to FIG. 5A and FIG. 5B, the chip on film 100 may include: a flexible substrate 1, and a multilayer wiring structure 10 disposed on the flexible substrate 1. In this embodiment, the multilayer wiring structure 10 may include a double-layer wiring structure. For example, the multilayer wiring structure 10 may include: a first wiring layer 11 disposed on the flexible substrate 1, where the first wiring layer 11 includes a first conductive material; a first insulation layer IL1 on a side of the first wiring layer 11 close to the flexible substrate 1; and a second wiring layer 12 disposed on a side of the first insulation layer IL1 close to the flexible substrate 1, where the second wiring layer 12 includes a second conductive material.

It should be noted that in the embodiments of the present disclosure, the flexible substrate 1 includes a first surface S1, and the first surface S1 of the flexible substrate 1 is a surface of the flexible substrate 1 close to the first wiring layer 11, namely an upper surface of the flexible substrate 1 shown in FIG. 5B. Herein, a thickness direction is defined as a first direction D1, that is, the first direction D1 is perpendicular to the first surface S1 of the flexible substrate, and is shown as a vertical direction in FIG. 5B.

With continued reference to FIG. 5A and FIG. 5B, the chip on film 100 further includes: a plurality of pins 111, at least part of which are in the first wiring layer 11; a plurality of first via holes VH1 in the first insulation layer IL1; and a second wire 121 and a second wire leading portion 122 which are in the second wiring layer 12. The second wire 121 is electrically connected to the second wire leading portion 122. More than one pin 111 is electrically connected to the second wire leading portion 122 through more than one first via hole VH1, respectively.

Optionally, the chip on film 100 further includes a first wire 112 in the first wiring layer 11. The first wire 112 is electrically connected to part of the plurality of pins 111. For example, thicknesses of the plurality of pins 111 in the first direction D1 are greater than a thickness of the first wire 112 in the first direction D1.

With reference to FIG. 5B, the chip on film 100 further includes an adhesive overflow space ASP between at least two adjacent pins 111 among the plurality of pins 111. The first insulation layer IL1 includes a first insulation surface ILS away from the flexible substrate 1. The first insulation surface ILS includes a first insulation surface portion ILS1 and a second insulation surface portion ILS2. An orthographic projection of the first insulation surface portion ILS1 on the flexible substrate 1 at least partially overlaps with an orthographic projection of more than one pin 111 on the flexible substrate 1. An orthographic projection of the second insulation surface portion ILS2 on the flexible substrate 1 at least partially overlaps with an orthographic projection of the adhesive overflow space ASP on the flexible substrate 1. At least part of a surface of the more than one pin 111 close to the flexible substrate 1 is in contact with the first insulation surface portion ILS1, at least part of the second insulation surface portion ILS2 serves as a bottom surface of the adhesive overflow space ASP, and the first insulation surface portion ILS1 and the second insulation surface portion ILS2 are in a same plane.

In the embodiments of the present disclosure, as shown in FIG. 5B, two side surfaces, opposite to each other, of the at least two adjacent pins 111 among the plurality of pins 111 serve as side surfaces of the adhesive overflow space ASP.

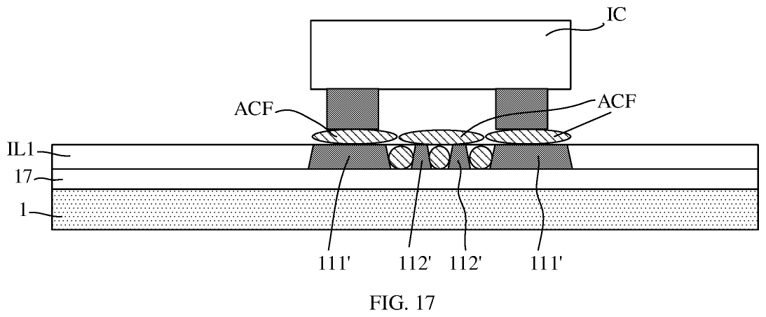

FIG. 17 is a schematic diagram schematically showing a sectional structure of a chip on film in related art. In the related art, with reference to FIG. 17, the chip on film 100′ includes the plurality of pins 111′ and the plurality of wires 112′ which are in a same layer. A thickness of the pin 111′ in the first direction DI is equal to a thickness of the wire 112′ in the first direction D1, that is, there is no step difference between the pin 111′ and its adjacent wire 112′. For example, in a bonding process for the chip on film 100′ to the chip IC, the pin 111′ may be bonded to the pins of the chip IC through anisotropic conductive film (ACF). In an actual bonding process, the anisotropic conductive film is mainly located between the pin 111′ and a pin of the chip IC, and the anisotropic conductive film may overflow to nearby areas. In the related art, there is no step difference between the pin 111′ and the adjacent wire 112′, resulting in a small adhesive overflow space for the anisotropic conductive film. Gold balls in the anisotropic conductive film will cause connection between the wires 112′ when the chip IC is pressed down, as shown in FIG. 17.

In the embodiments of the present disclosure, for example, in a process of bonding the chip on film 100 to the chip IC, the display panel 100, or the circuit board 300, the pin 111 may be bonded to an object to be bonded through an anisotropic conductive film (ACF). In the actual bonding process, the anisotropic conductive film is mainly located between the pin 111 and the object to be bonded, so as to bond the pin 111 and the object to be bonded, and conduct a path between the pin 111 and the bonding object, and at the same time, the anisotropic conductive film may overflow to nearby areas. In this case, in order to provide sufficient adhesive overflow space and ensure the bonding quality, an adhesive overflow space ASP is provided between the at least two adjacent pins 111 among the plurality of pins 111. That is, a vertical distance H1 between an upper surface of the pin 111 (i.e. a surface away from the flexible substrate 1) and the upper surface S1 of the flexible substrate 1 is greater than a vertical distance H2 between an upper surface of the first insulation layer adjacent to the pin 111 and the upper surface S1 of the flexible substrate 1.

For example, in order to ensure sufficient adhesive overflow space while reducing product sizes, a difference between the vertical distance H1 and the vertical distance H2 may be in a range of 2 μm to 8 μm. For example, the difference may be 2 μm, 4 μm, 6 μm or 8 μm.

The inventors found through research that in the conventional chip on film, a technical material, such as titanium/aluminum/titanium, used as a conductive material of the wiring layer may cause high impedance of an output terminal and serious heat generation problem of the wires.

In the embodiments of the present disclosure, both the first conductive material and the second conductive material include copper. That is to say, in the embodiments of the present disclosure, multiple layers of wires adopt metal copper with lower resistivity, so as to effectively reduce the wire resistance and improve the heat generation problem of the wires. Moreover, each pin adopts a thick copper structure, so as to effectively reduce a bonding resistance.

For example, in the first direction D1, the thickness of the first wire 112 is equal to a thickness of the second wire 121.

Orthographic projections of the plurality of pins 111 on the flexible substrate 1 are arranged in an array. Orthographic projections of part of the plurality of pins 111 on the flexible substrate 1 at least partially overlaps with an orthographic projection of the second wire leading portion 122 on the flexible substrate 1. For example, the plurality of pins 111 may be arranged in a plurality of rows, such as 2 rows, 3 rows, 4 rows or 5 rows. A direction in which more than one pin in each row is arranged and a direction in which the plurality of rows are arranged are not limited. For example, the plurality of rows may be arranged vertically or obliquely, and in each row, more than one pin may be arranged vertically or obliquely, so as to form an arrangement of the Chinese character “ [symbol] ”.

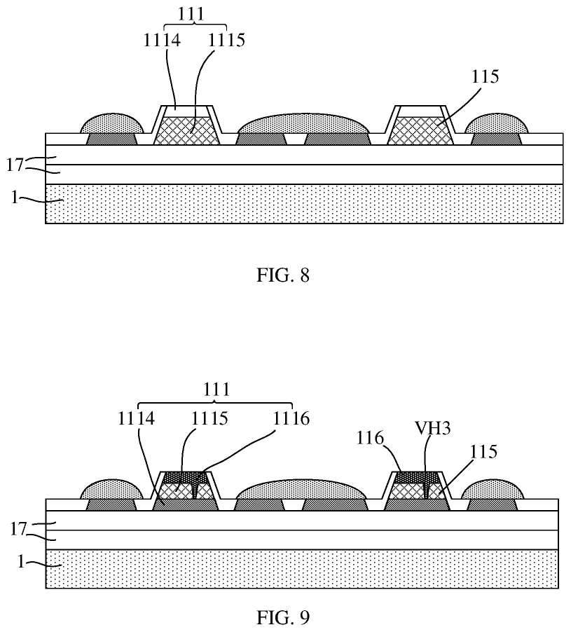

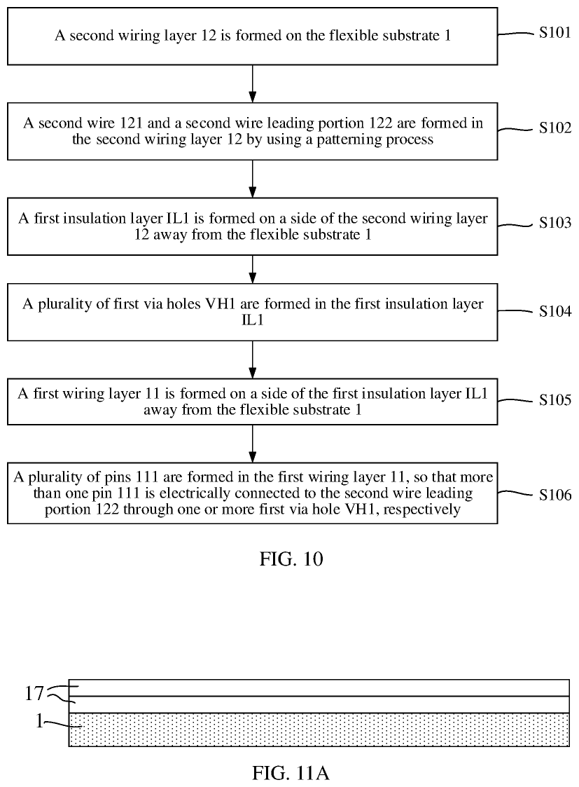

FIG. 6A is a schematic diagram schematically showing a planar structure of a multilayer wiring structure included in a chip on film according to some other embodiments of the present disclosure. FIG. 6B is a schematic diagram schematically showing a sectional structure of a multilayer wiring structure included in a chip on film according to some other embodiments of the present disclosure. With reference to FIG. 6A and FIG. 6B, the chip on film 100 may include: a flexible substrate 1; and a multilayer wiring structure 10 disposed on the flexible substrate 1. In this embodiment, the multilayer wiring structure 10 may include a three-layer wiring structure. For example, the multilayer wiring structure 10 may include a first wiring layer 11 disposed on the flexible substrate 1, where the first wiring layer 11 includes the first conductive material; a first insulation layer IL1 on a side of the first wiring layer 11 close to the flexible substrate 1; and a second wiring layer 12 disposed on a side of the first insulation layer IL1 close to the flexible substrate 1, where the second wiring layer 12 includes a second conductive material; a second insulation layer IL2 on a side of the second wiring layer 12 close to the flexible substrate 1; and a third wiring layer 13 on a side of the second insulation layer IL2 close to the flexible substrate 1, where the third wiring layer 13 includes a third conductive material.

Each of the first conductive material, the second conductive material and the third conductive material includes copper. In the embodiments of the present disclosure, the multiple layers of wires adopt metal copper with lower resistivity, so as to effectively reduce the wire resistance. Moreover, each pin adopts a thick copper structure, so as to effectively reduce the bonding resistance.

In this embodiment, the chip on film 100 further includes: a plurality of second via holes VH2 in the second insulation layer IL2; a transition portion 123 in the second wiring layer 12; and a third wire 131 and a third wire leading portion 132 which are in the third wiring layer 13. The third wire 131 is electrically connected to the third wire leading portion 132.

Part of the plurality of pins 111 are electrically connected to the transition portion 123 through more than one first via hole VH1, respectively, and the transition portion 123 is electrically connected to the third wire leading portion 132 through more than one second via hole VH2.

In the embodiments of the present disclosure, the chip on film 100 has a multilayer wiring structure, which includes more than 2 wiring layers for arranging structures of the chip on film 100, such as wires, wire leading portions, transition portions and pins, in the layers, respectively. In the above embodiments, the exemplary descriptions of the multilayer wiring structure include 2 wiring layers and 3 wiring layers. It should be understood that the embodiments of the present disclosures are not limited thereto, and the chip on film 100 provided by the embodiments of the present disclosures may also include more wiring layers (such as 4, 5, 6 or more layers).

In the embodiments of the present disclosure, for the convenience of description, an uppermost wiring layer (i.e. a wiring layer farthest away from the flexible substrate 1) in the multilayer wiring structure is referred to as a first wiring layer. On this basis, along a direction pointing from the first wiring layer towards the flexible substrate, other wiring layers are sequentially referred to as a second wiring layer, a third wiring layer, and so on.

It should be understood that in any one of the wiring layers, at least one structure such as a wire, a wire leading portion, a transition portion and a pins is provided. Unless otherwise specified, the expression “wire” herein is used to represent a signal line used for transmitting a signal; the expression “wire leading portion” herein is used to represent a portion electrically connected to the wire for leading out the wire; the expression “pin” herein is used to represent a portion disposed on the chip on film and electrically connected to other leads, wires, electrodes, etc., including but not limited to a pad on the chip on film; and the expression “transition portion” herein is used to represent a portion disposed on the chip on film for connecting the wire and the wire leading portion to the pin.

For example, in the embodiments of the present disclosure, a plurality of pins 111 may be disposed in the first wiring layer 11. The chip on film 100 may be electrically connected to at least one of the integrated circuit IC, the display panel 200 and the circuit board 300 through the plurality of pins 111. Optionally, at least one first wire 112 may further be provided in the first wiring layer 11.

For example, in the embodiments of the present disclosure, the second wiring layer 12 may be provided with a plurality of second wires 121 and a plurality of second wire leading portions 122. Optionally, at least one transition portion may also be provided in the second wiring layer 12. For example, the second wire 121 may be led out through the second wire leading portion 122, and then may be electrically connected to the pin 111 through the first via VH1. That is to say, the second wire, the second wire leading portion and the corresponding pin are electrically connected to one another. The second wire and the second wire leading portion may be disposed in a same layer. Orthographic projections of the second wire leading portion and the second wire on the flexible substrate may respectively overlap or not overlap with an orthographic projection of the pin on the flexible substrate.

In order to reduce parasitic capacitance, as shown in FIG. 5A, the orthographic projection of the second wire 121 on the flexible substrate does not overlap with the orthographic projection of the pin 111 on the flexible substrate. Optionally, in order to save space and reduce spacing, the orthographic projection of the second wire 122 on the flexible substrate may overlap with the orthographic projection of the pin 111 on the flexible substrate.

For example, the orthographic projection of the second wire leading portion 122 on the flexible substrate 1 falls within the orthographic projection of the pin 111 on the flexible substrate 1.

In the embodiments of the present disclosure, by providing the multilayer wiring structure, at least one of the following effects may be achieved: (1) the wires, the pins and other structures may be provided in multiple layers, so that more pins may be provided, thus it is beneficial to the increase of the number of output channels in the chip encapsulation structure, and correspondingly, the resolution of the display device may be improved; (2) in a case that the number of pins remains the same, the pin spacing may be shortened and the number of wire rows may be reduced, and thus, one chip on film may correspond to a plurality of chips, so as to improve the chip integration and reduce a width of a bonding border; and (3) in a case that the number of wires remains the same, by providing the wires in multiple layers, a width of the wire in each layer may be designed wider, which is beneficial to reduction of the wire resistance.

It should be noted that as shown in FIG. 6A, a wire spacing refers to a sum of a width W1 of a wire and a spacing DP1 between adjacent wires, and a pin spacing refers to a sum of a width W2 of a pin and a spacing DP2 between adjacent pins.

In the embodiments of the present disclosure, the plurality of pins 111 have substantially a same thickness in the first direction D1. The thickness of the plurality of pins 111 in the first direction D1 is greater than a thickness of the first wire 112 in the first direction D1. The thicknesses of the plurality of pins 111 in the first direction D1 is greater than a thickness of the second wire 121 in the first direction or a thickness of the second wire leading portion 122 in the first direction D1. For example, in a case of using metal copper as a wire material, a thickness of the second wiring layer may be in a range of 200 nm to 2000 nm. Correspondingly, the thickness of the second wire in the second wiring layer, the thickness of the second wire leading portion in the second wiring layer and the thickness of the transition portion in the second wiring layer may all be in a range of 200 nm to 2000 nm.

Optionally, in a case that the pin 111 is made of a material that is prone to oxidation (such as copper), in order to avoid copper oxidation, an anti-oxidation layer 15 is provided. With reference back to FIG. 5B, the chip on film 100 further includes the anti-oxidation layer 15 on a side of the first wiring layer 11 away from the flexible substrate 1. At least one anti-oxidation portion 151 provided in the anti-oxidation layer 15 covers at least one pin 111.

For example, the anti-oxidation layer 15 may be formed by using a process such as chemical plating of Sn or Au, and a thickness of the anti-oxidation layer 15 is in a range of 0.5 μm to 2 μm. Alternatively, ITO (Indium Tin Oxide) may be used to cover the surface of the pin 111, so as to prevent oxidation. In addition, the anti-oxidation layer is also beneficial to the increase of a height of the area in which the pin is located, thereby ensuring sufficient adhesive overflow space during the subsequent bonding process.

In order to protect a non-bonding area, optionally, the chip on film 100 may include a solder resist layer (such as liquid photoimageable solder mask) 18. A thickness of the solder resist layer is in a range of 5 μm to 20 μm. For example, the solder resist layer 18 may be between at least two adjacent pins 111, that is, the solder resist layer 18 may be in the adhesive overflow space ASP.

In order to reduce the resistance of the wire and improve the conductivity of the pin, metal copper is used as the conductive material of the wiring layer. In this case, in order to ensure that a thickness of the copper pin is in a range of 10 μm to 15 μm, usually, the copper pin may be manufactured by using an electroplating additive method. The inventors found through research that in the formation of the copper wiring layer by using the additive method, characteristics of the electroplating process may lead to uneven thicknesses of the manufactured copper pins due to factors such as the electroplating device (such as the current distribution) and the electroplating solution. For example, the copper pin exhibits a thickness trend of thick on both sides and thin in the middle, and a thickness difference of the copper pin may be greater than 2 μm, which may pose significant difficulties for subsequent bonding processes. In addition, the manufacturing process of the copper pin using the electroplating additive method is complex and at high costs.

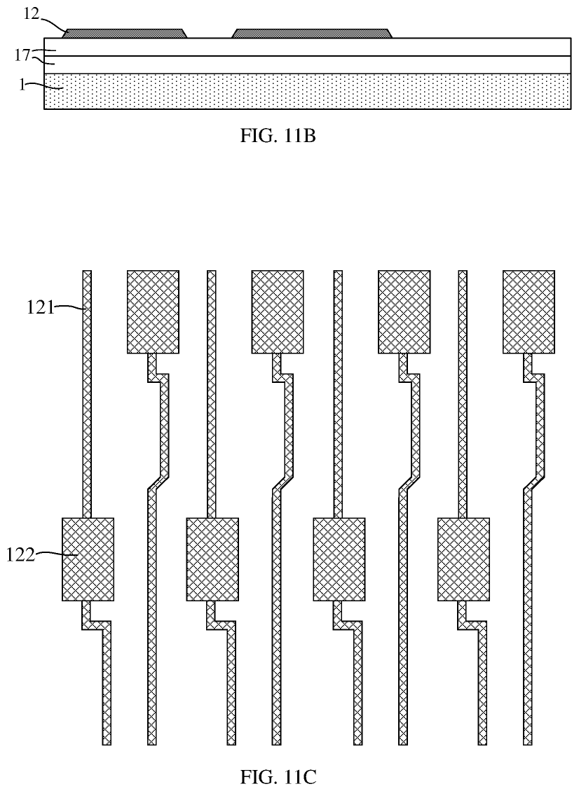

FIG. 7 shows a schematic diagram of a chip on film according to some other embodiments of the present disclosure, where a pin of the chip on film includes a portion formed by an electroless nickel immersion gold process. With reference to FIG. 7, the chip on film 100 further includes an anti-oxidation layer 114 located on a side of the first wiring layer 11 away from the flexible substrate 1, where a material of the anti-oxidation layer 114 includes a gold nickel alloy. In this embodiment, at least one pin 111 includes a first sub-pin 1111 in the first wiring layer 11 and a second sub-pin 1112 in the anti-oxidation layer 114. In a same pin 111, the second sub-pin 1112 covers the first sub-pin 1111.

In the first direction D1, a thickness of the second sub-pin 1112 is greater than a thickness of the first sub-pin 1111 covered by the second sub-pin 1112.

In this embodiment, the second sub-pin 1112 in the anti-oxidation layer 114 includes a gold nickel alloy. The second sub-pin 11 is formed by using the electroless nickel immersion gold process during the process of forming the thick copper pin using a combination of the subtractive method and the electroless nickel immersion gold process. In this way, a combination of a subtractive method and the chemical gilding process may be used to form the thick copper pin, so as to ensure a low bonding resistance and improve a thickness uniformity of the pin.

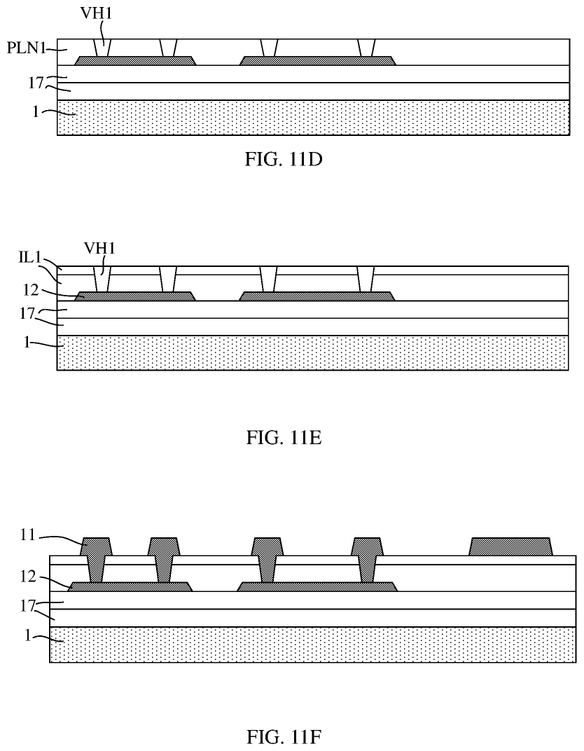

FIG. 8 shows a schematic diagram of a chip on film according to some other embodiments of the present disclosure, where a pin of the chip on film includes one height adjustment portion. With reference to FIG. 8, the chip on film 100 further includes a first height adjustment layer 115 locate between the first wiring layer 11 and the first insulation layer IL1. At least one pin 111 includes a first pin 1114 in the first wiring layer 11 and a first height adjustment unit 1115 in the first height adjustment layer 115. In a same pin 111, an orthographic projection of the first pin 1114 on the flexible substrate 1 falls within an orthographic projection of the first height adjustment portion 1115 on the flexible substrate 1.

A material of the first height adjustment layer 115 is different from that of the first insulation layer IL1. The material of the first height adjustment layer 115 is different from that of the first wiring layer 11.

In this embodiment, the pin 111 includes the first pin 1114 made of metal copper and the first height adjustment portion 1115 made of resin or other materials. A suitable adhesive overflow space may be formed by adjusting a thickness of the first height adjustment portion 1115, and accordingly, a thickness of the first pin 1114 made of copper metal may be reduced. In this case, it is not required to use thick copper manufacturing processes such as the electroplating additive method to manufacture the pin. Therefore, in this embodiment, it is beneficial to achieve a uniform thickness of the pin.

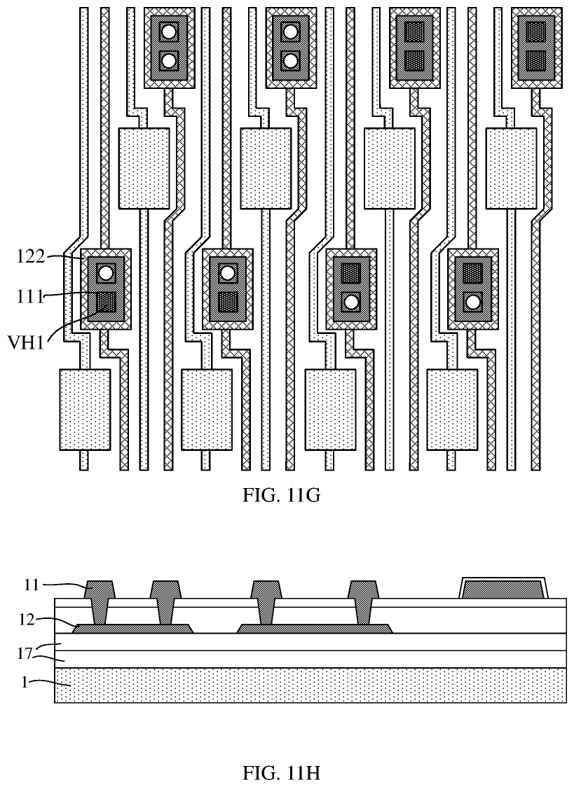

FIG. 9 shows a schematic diagram of a chip on film according to some other embodiments of the present disclosure, where a pin of the chip on film includes two height adjustment portions. With reference to FIG. 9, the chip on film 100 further includes a first height adjustment layer 115 on a side of the first wiring layer 11 away from the flexible substrate 1, and a second height adjustment layer 116 on a side of the first height adjustment layer 115 away from the flexible substrate 1.

At least one pin 111 includes: a first pin 1114 in the first wiring layer 11, a first height adjustment portion 1115 in the first height adjustment layer 115, and a second height adjustment portion 1116 in the second height adjustment layer 116. In a same pin 111, an orthographic projection of the second height adjustment portion 1116 on the flexible substrate 1 falls within an orthographic projection of the first height adjustment portion 1115 on the flexible substrate 1, and the orthographic projection of the first height adjustment portion 1115 on the flexible substrate 1 falls within an orthographic projection of the first pin 1114 on the flexible substrate 1.

The second height adjustment layer 116 includes a conductive material. The second height adjustment portion 1116 is electrically connected to the first pin 1114 through a third via hole VH3 penetrating the first height adjustment portion 1115.

A material of the first height adjustment layer 115 is different from that of the first wiring layer 11. The material of the first height adjustment layer 115 is different from that of the second height adjustment layer 116.

The first insulation layer IL1 includes a first inorganic insulation layer IL11 and a first planarization layer PLN1. The first inorganic insulation layer IL11 is between the first wiring layer 11 and the first planarization layer PLN1, and the first insulation surface ILS is a surface of the first inorganic insulation layer IL11 away from the flexible substrate 1.

A thickness of the first height adjustment portion 1115 in the first direction D1 is more than 2 μm; and/or, a thickness of the second height adjustment portion 1116 in the first direction D1 is more than 2 μm.

In this embodiment, the pin 111 includes a first pin 1114 made of metal copper, a first height adjustment portion 1115 made of resin or other materials, and a second height adjustment portion 1116 made of a conductive material. A suitable adhesive overflow space may be formed by adjusting a thickness of at least one of the first height adjustment portion 1115 and the second height adjustment portion 1116, and accordingly, a thickness of the first pin 1114 made of metal copper may be reduced. In this case, it is not required to use thick copper manufacturing processes such as the electroplating additive method to manufacture the pin. Therefore, in this embodiment, it is beneficial to achieve uniform thickness of the pin.

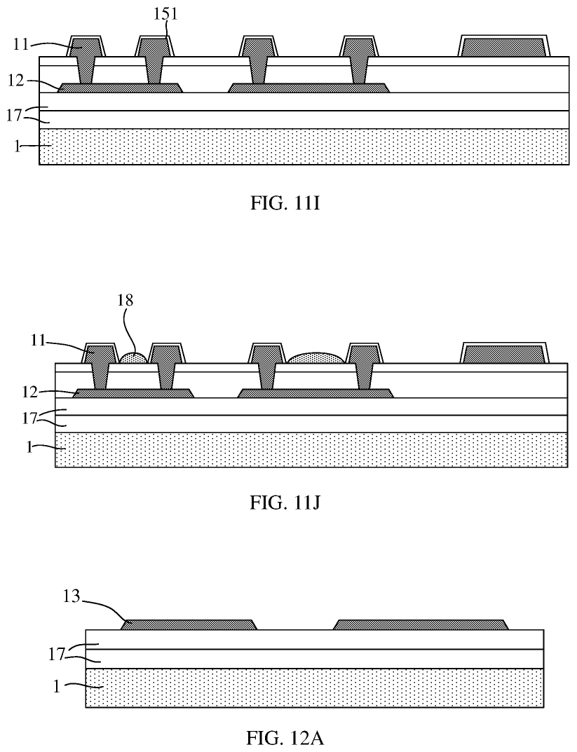

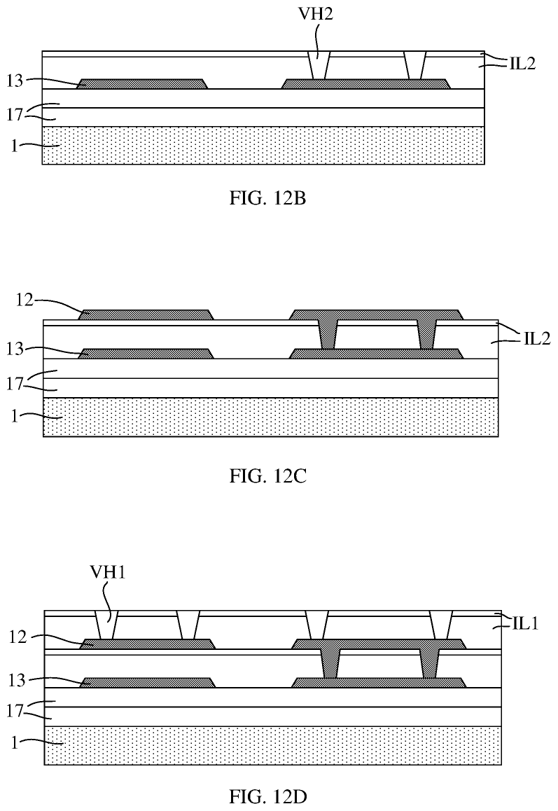

An embodiment of the present disclosure further provide a method for manufacturing a chip on film. FIG. 10 shows a flowchart of a method for manufacturing a chip on film according to an embodiment of the present disclosure. FIG. 11A to FIG. 11J show schematic diagrams of structures formed after some steps of a method for manufacturing a chip on film according to an embodiment of the present disclosure are performed. With reference to FIG. 10 and FIG. 11A to FIG. 11J, the method for manufacturing the chip on film may include steps S101 to S106.

In step S101, a second wiring layer 12 is formed on the flexible substrate 1. The second wiring layer includes a second conductive material. For example, the second conductive material may include copper. In this case, a thickness of the second wiring layer 12 may be in a range of 200 nm to 2000 nm.

In step S102, a second wire 121 and a second wire leading portion 122 are formed in the second wiring layer 12 by using a patterning process. The second wire 121 is electrically connected to the second wire leading portion 122.

In step S103, a first insulation layer IL1 is formed on a side of the second wiring layer 12 away from the flexible substrate 1. For example, a first planarization layer PLN1 may be coated on a side of the second wiring layer 12 away from the flexible substrate 1. For example, a material of the first planarization layer PLN1 may include resin, and a thickness of the first planarization layer PLN1 may be in a range of 2 μm to 5 μm. The first inorganic insulation layer IL11 may be deposited on a side of the first planarization layer PLN1 away from the flexible substrate 1. For example, a material of the first inorganic insulation layer IL11 may include silicon oxide or silicon nitride, and a thickness of the first inorganic insulation layer IL11 is in a range of 100 nm to 500 nm.

In step S104, a plurality of first via holes VH1 are formed in the first insulation layer IL1. For example, the plurality of first via holes VH1 may be formed in the first planarization layer PLN1 and the first inorganic insulation layer IL 11 through a patterning process or a dry etching process. For example, the plurality of first via holes VH1 may be respectively formed in the first planarization layer PLN1 and the first inorganic insulation layer IL 11 through the patterning process or the dry etching process.

In step S105, a first wiring layer 11 is formed on a side of the first insulation layer IL1 away from the flexible substrate 1, and the first wiring layer 11 includes a first conductive material. For example, the first conductive material may include copper. In this case, a thickness of the first wiring layer 11 may be in a range of 2 μm to 16 μm.

In step S106, a plurality of pins 111 are formed in the first wiring layer 11. More than one pin 111 is electrically connected to the second wire leading portion 122 through more than one first via hole VH1, respectively.

The chip on film 100 further includes an adhesive overflow space ASP between at least two adjacent pins 111 among the plurality of pins 111. The first insulation layer IL1 includes a first insulation surface ILS away from the flexible substrate 1. The first insulation surface ILS includes a first insulation surface portion ILS1 and a second insulation surface portion ILS2. An orthographic projection of the first insulation surface portion ILS1 on the flexible substrate 1 at least partially overlaps with an orthographic projection of more than one pin 111 on the flexible substrate 1. An orthographic projection of the second insulation surface portion ILS2 on the flexible substrate 1 at least partially overlaps with an orthographic projection of the adhesive overflow space ASP on the flexible substrate 1. At least part of a surface of the more than one pin 111 close to the flexible substrate 1 is in contact with the first insulation surface portion ILS1, at least part of the second insulation surface portion ILS2 serves as a bottom surface of the adhesive overflow space ASP, and the first insulation surface portion ILS1 and the second insulation surface portion ILS2 are in a same plane.

Optionally, in a case that the pin 111 is made of a material that is prone to oxidation (such as copper), in order to avoid copper oxidation, the method may further include providing an anti-oxidation layer 15 to cover the pin 111. For example, the anti-oxidation layer 15 may adopt processes such as chemical plating of Sn or Au, and a thickness of the anti-oxidation layer 15 is in a range of 0.5 μm to 2 μm. Alternatively, ITO (indium tin oxide) may be used to cover the surface of the pin 111, so as to prevent oxidation.

In order to protect a non-bonding area, optionally, the method may include brushing a solder resist layer (such as liquid photoimageable solder mask) 18 to the adhesive overflow space ASP. A thickness of the solder resist layer is in a range of 5 μm to 20 μm.

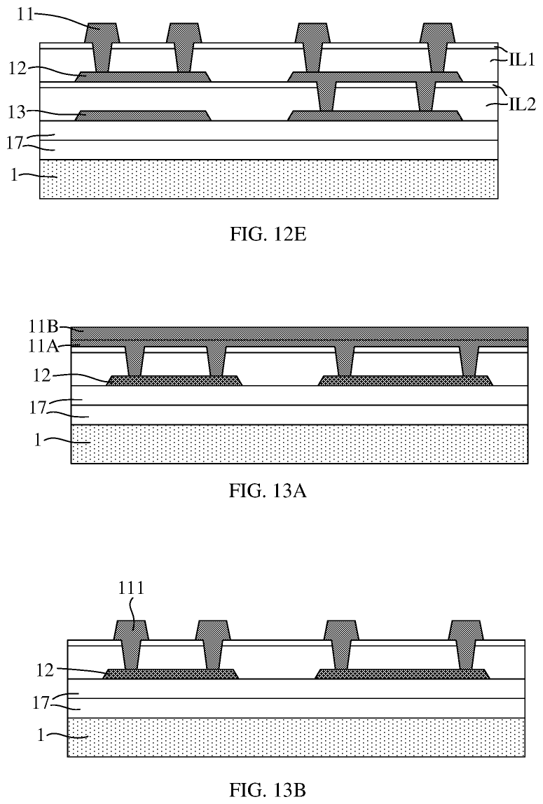

Optionally, with reference to FIG. 12A to FIG. 12E, a three-layer wiring structure may be formed. In the embodiments of the present disclosure, before step S101, a third wiring layer 13 may be formed on the flexible substrate 1, where the third wiring layer 13 includes a third conductive material. For example, the third conductive material may include copper. In this case, a thickness of the third wiring layer 13 may be in a range of 200 nm to 2000 nm. By using a patterning process, a third wire 131 and a third wire leading portion 132 are formed in the third wiring layer 13, where the third wire 131 is electrically connected to the third wire leading portion 132. Then, a second insulation layer IL2 is formed on a side of the third wiring layer 13 away from the flexible substrate 1. For example, a planarization layer may be coated on the side of the third wiring layer 13 away from the flexible substrate 1. For example, a material of the planarization layer PLN1 may include resin, and a thickness of the planarization layer PLN1 may be in a range of 2 μm to 5 μm. An inorganic insulation layer may be deposited on a side of the planarization layer away from the flexible substrate 1. For example, a material of the inorganic insulation layer may include silicon oxide or silicon nitride, and a thickness of the inorganic insulation layer may be in a range of 100 nm to 500 nm. A plurality of second via holes VH2 are formed in the second insulation layer IL2.

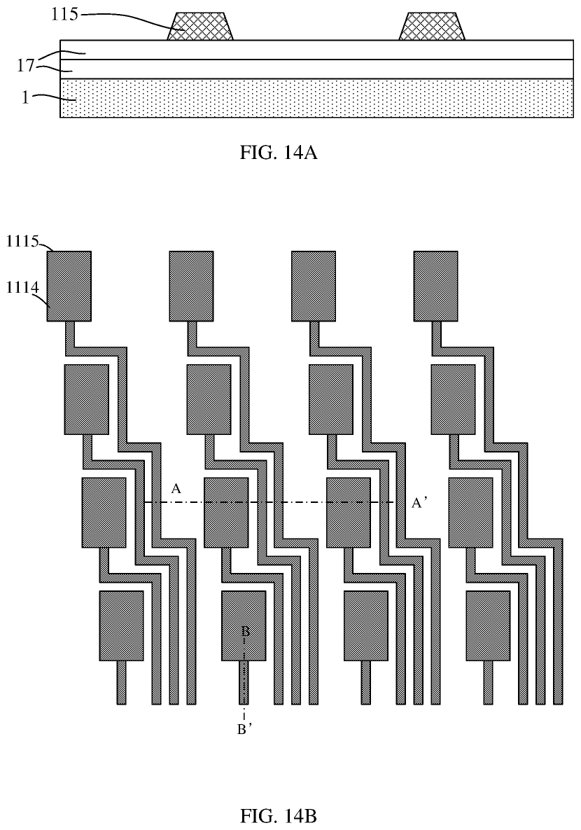

With reference to FIG. 13A to FIG. 13B, in some embodiments of the present disclosure, the first conductive material includes copper. In step S105, forming the first wiring layer 11 on the side of the first insulation layer IL1 away from the flexible substrate 1 includes: forming a copper seed layer 11A on the side of the first insulation layer away from the flexible substrate; and electroplating a copper layer 11B on a surface of the copper seed layer 11A away from the flexible substrate 1, so as to form the first wiring layer 11 including the copper seed layer and the copper layer.

For example, in step S105, the copper seed layer 11A with a thickness of about 3000 angstroms is deposited on the side of the first insulation layer IL1 away from the flexible substrate 1, and then, the copper layer 11B with a thickness in a range of 1 μm to 5 μm is electroplated on the surface of the copper seed layer 11A away from the flexible substrate 1. In this way, in the following processes, the pin 111 may be formed in the first wiring layer 11 including the copper seed layer and the copper layer by using a patterning process. That is to say, in the embodiments of the present disclosure, a copper pin may be manufactured by using the subtractive method, which is beneficial to the improvement of the thickness uniformity of the pin.

Correspondingly, in step S106, forming the plurality of pins 111 in the first wiring layer 11 includes: performing a patterning process on the first wiring layer 11 including the copper seed layer and the copper layer to form a first sub-pin 1111; and performing an electroless nickel immersion gold process on the first sub-pin 1111 to form a second sub-pin 1112 covering the first sub-pin 1111. In the embodiments of the present disclosure, the electroless nickel immersion gold process is performed on the copper pin 1111, so as to form the second sub-pin 1112 made of a gold nickel alloy and covering the copper pin 1111, thereby preventing oxidation while permitting the copper pin 1111 to continue to grow to a target thickness, such as 8 μm to 12 μm, as shown in FIG. 7. In addition, since the second sub-pin 1112 made of the gold nickel alloy grows both upwards and towards its periphery in the electroless nickel immersion gold process, the copper pin needs to be correspondingly reduced. Taking the target thickness of 8 μm as an example, where a thickness of the first sub-pin 1111 is about 3 μm and a thickness of the second sub-pin 1112 is about 5 μm, an opening of a mask for forming the first sub-pin 1111 by using the subtractive method is 2 μm smaller than an opening of a mask for forming the pin by using the additive method.

In this embodiment, a combination of the subtractive method and the chemical gilding process is used to form a thick copper pin, so as to ensure low bonding resistance and improve thickness uniformity of the pin.

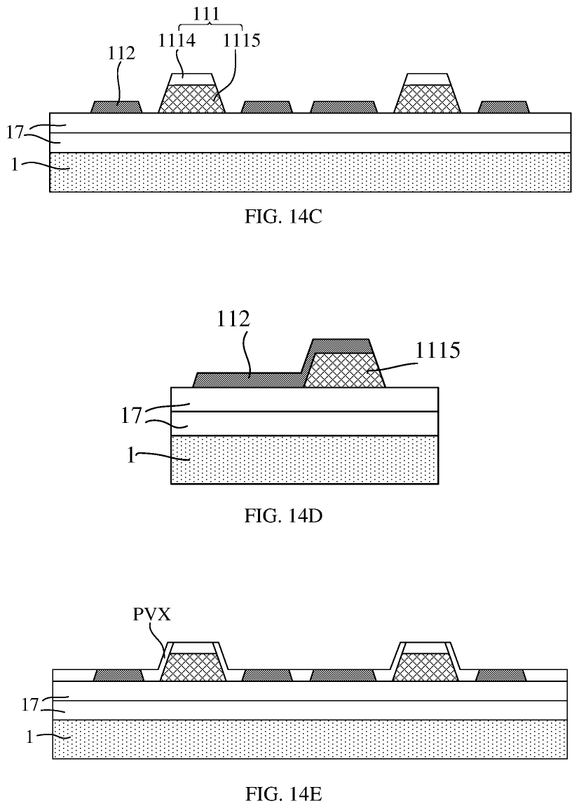

With reference to FIG. 14A to FIG. 14E, optionally, before forming the first wiring layer 11, the method may further include: forming a first height adjustment layer 115 on a side of the first insulation layer IL1 away from the flexible substrate 1; and performing a patterning process on the first height adjustment layer 115 to form a first height adjustment portion 1115 in the first height adjustment layer 115.

For example, the first height adjustment layer 115 may include an organic material such as resin. For example, the organic material may be coated on the whole surface to a certain thickness (such as 2 μm to 8 μm) by using spin coating and other methods. Then, the patterning of the organic material may be achieved by using a photolithography process. Finally, a curing process is performed on the organic material, so as to form the first height adjustment portion 1115. In this way, the organic material of the first height adjustment portion may be used to partially replace the metal material, so as to ensure the adhesive overflow space for bonding, and it is beneficial to the simplification of the process route.

Correspondingly, in step S106, forming the plurality of pins 111 in the first wiring layer 11 includes: performing a dry etching process on the first wiring layer 11 to form a first pin 1114, so that at least one pin 111 includes the first pin 1114 in the first wiring layer and the first height adjustment portion 1115 in the first height adjustment layer. In a same pin 111, an orthographic projection of the first pin 1114 on the flexible substrate 1 falls within an orthographic projection of the first height adjustment portion 1115 on the flexible substrate 1.

For example, in this embodiment, the first wiring layer 11 may include a stack formed of a titanium layer, an aluminum layer and a titanium layer. The Ti/Al/Ti has a conventional thickness of 500/6500/500 angstroms, which may meet requirements of wire pitch, pin arrangement and resistance. Alternatively, the first wiring layer 11 may include a single layer formed by a copper layer.

FIG. 14C is a sectional view taken along line AA′ in FIG. 14B. FIG. 14D is a sectional view taken along line BB′ in FIG. 14B. With reference to FIG. 14C and FIG. 14D, the first height adjustment portion 1115 is provided below the pin 114, and the wire 112 in the first wiring layer may be electrically connected to the pin 114 by climbing the first height adjustment portion 1115.

It should be noted that in the case of using Ti/Al/Ti as the wire metal, the wire may be formed more finely and patterned more precisely through the dry etching process.

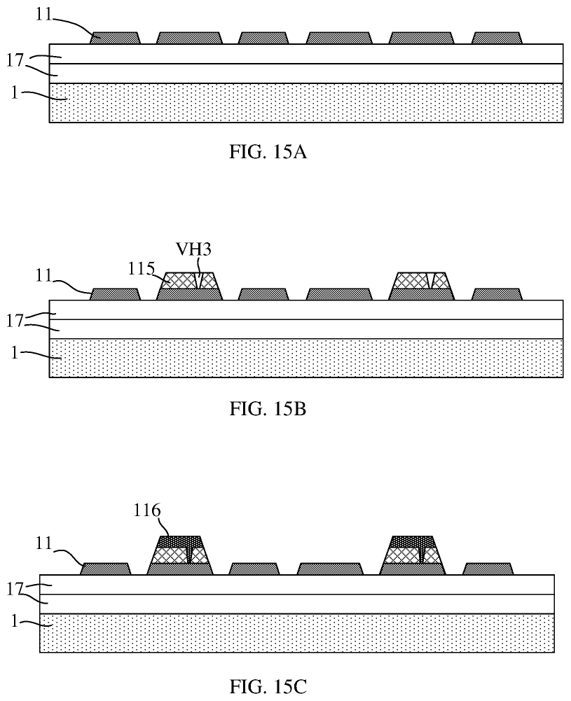

With reference to FIG. 15A to FIG. 15D, alternatively, in step S106, forming the plurality of pins 111 in the first wiring layer 11 includes: performing a dry etching process on the first wiring layer 11 to form the first pin 1114; forming the first height adjustment layer 115 on the side of the first pin 1114 away from the flexible substrate 1; performing a patterning process on the first height adjustment layer to form the first height adjustment portion 1115 and a third via hole VH3 penetrating the first height adjustment portion; forming a second height adjustment layer 116 on a side of the first height adjustment portion 1115 away from the flexible substrate 1; and performing a patterning process on the second height adjustment layer to form a second height adjustment portion 1116.

In this embodiment, in a same pin 111, an orthographic projection of the second height adjustment portion 1116 on the flexible substrate 1 falls within the orthographic projection of the first height adjustment portion 1115 on the flexible substrate 1, and the orthographic projection of the first height adjustment portion 1115 on the flexible substrate 1 falls within the orthographic projection of the first pin 1114 on the flexible substrate 1.

In this embodiment, the first height adjustment layer 115 may include an organic material such as resin. A material of the second height adjustment portion 1116 may be the same as a material of the first pin 1114. For example, the second height adjustment portion 1116 and the first pin 1114 may both include a stack formed of a titanium layer, an aluminum layer and a titanium layer. Alternatively, the second height adjustment portion 1116 and the first pin 1114 may both include a single layer formed of a copper layer.

It should be noted that some steps of the above manufacturing method may be performed separately or in combination, and may be performed in parallel or sequentially, which is not limited to the specific operating sequence shown in the figure.

It should also be noted that, in some embodiments, the display device provided in the present disclosure may be a liquid crystal display device, or an organic light emitting diodes (OLED) display panel, or a quantum dot light emitting Diodes (QLED) display panel, which is not limited herein. In some embodiments, the display device provided by the embodiments of the present disclosure may be a 3D display device or other display device, and may be any product or component with display functions, such as a mobile phone, a tablet, a TV, a monitor, a laptop, a digital photo frame, a navigator, a smart watch, a fitness wristband, a personal digital assistant. Optionally, the display device provided in the embodiments of the present disclosure includes but is not limited to: a radio frequency unit, a network module, an audio output & input unit, a sensor, a display unit, a user input unit, an interface unit, a control chip, and other components. Optionally, the control chip is a central processing unit, a digital signal processor, a system on chip (SoC), etc. For example, the control chip may further include a memory, may further include a power module, etc., and may achieve power supply and signal input and output functions through separately providing wires, signal lines, etc. For example, the control chip may further include a hardware circuit and computer executable codes. In addition, those skilled in the art may understand that the above structures do not constitute a limitation on the display device provided in the embodiments of the present disclosure. In other words, the display device provided in the embodiments of the present disclosure may include more or fewer components, or combinations of certain components, or different component arrangements.

In the present disclosure, the terms “basically”, “about”, “approximately” and other similar terms are used as approximate terms rather than as terms of degree, and they are intended to explain the fixed deviation of measured or calculated values that will be recognized by those of ordinary skilled in the art. Taking into account factors such as process fluctuations, measurement problems and errors related to the measurement of a specific amount (i.e., the limitations of the measurement system), the “about” or “approximately” used here includes the stated value, and indicates that the specific value determined by ordinary technicians in the art is within the acceptable deviation range. For example, “about” may be expressed within one or more standard deviations, or within ±10% or ±5% of the stated values.

Although some embodiments of the general technical concept of the present disclosure have been shown and described, those of ordinary skilled in the art will understand that changes may be made to these embodiments without departing from the principle and spirit of the general technical concept. The scope of the present disclosure is defined by the claims and their equivalents.

1. A chip on film, comprising:
a flexible substrate; and
a multilayer wiring structure disposed on the flexible substrate, comprising:
a first wiring layer disposed on the flexible substrate, wherein the first wiring layer comprises a first conductive material;
a first insulation layer disposed on a side of the first wiring layer close to the flexible substrate; and
a second wiring layer disposed on a side of the first insulation layer close to the flexible substrate, wherein the second wiring layer comprises a second conductive material,
wherein the chip on film further comprises: a plurality of pins, at least part of which is located in the first wiring layer; a plurality of first via holes in the first insulation layer; and a second wire and a second wire leading portion which are in the second wiring layer, wherein the second wire is electrically connected to the second wire leading portion, and more than one pin is electrically connected to the second wire leading portion through more than one first via hole, respectively,
wherein the chip on film further comprises an adhesive overflow space between at least two adjacent pins among the plurality of pins, the first insulation layer comprises a first insulation surface away from the flexible substrate, the first insulation surface comprises a first insulation surface portion and a second insulation surface portion, an orthographic projection of the first insulation surface portion on the flexible substrate at least partially overlaps with an orthographic projection of more than one pin on the flexible substrate, an orthographic projection of the second insulation surface portion on the flexible substrate at least partially overlaps with an orthographic projection of the adhesive overflow space on the flexible substrate, at least part of a surface of the more than one pin close to the flexible substrate is in contact with the first insulation surface portion, at least part of the second insulation surface portion serves as a bottom surface of the adhesive overflow space, and the first insulation surface portion and the second insulation surface portion are in a same plane.

2. The chip on film of claim 1, wherein the flexible substrate comprises a first surface, and the first surface of the flexible substrate is a surface of the flexible substrate close to the first wiring layer, the plurality of pins have substantially a same thickness in a first direction, wherein the first direction is a direction perpendicular to the first surface of the flexible substrate.

3. The chip on film of claim 1, wherein two side surfaces of the at least two adjacent pins among the plurality of pins serve as side surfaces of the adhesive overflow space, wherein the two side surfaces opposite to each other.

4. The chip on film of claim 2, wherein the chip on film further comprises a first wire in the first wiring layer, the first wire is electrically connected to part of the plurality of pins, and thicknesses of the plurality of pins in the first direction are greater than a thickness of the first wire in the first direction.

5. The chip on film of claim 4, wherein the thicknesses of the plurality of pins in the first direction are greater than a thickness of the second wire in the first direction or a thickness of the second wire leading potion in the first direction.

6. The chip on film of claim 1, further comprising: a second insulation layer disposed on a side of the second wiring layer close to the flexible substrate; and a third wiring layer disposed on a side of the second insulation layer close to the flexible substrate, wherein the third wiring layer comprises a third conductive material,
wherein the chip on film further comprises: a plurality of second via holes in the second insulation layer; a transition portion in the second wiring layer; and a third wire and a third wire leading portion which are in the third wiring layer, wherein the third wire is electrically connected to the third wire leading portion,
part of the plurality of pins are electrically connected to the transition portion through more than one first via hole, respectively, and the transition portion is electrically connected to the third wire leading portion through more than one second via hole.

7. The chip on film of claim 1, further comprising an anti-oxidation layer on a side of the first wiring layer away from the flexible substrate, and at least one anti-oxidation portion in the anti-oxidation layer covers at least one pin.

8. The chip on film of claim 1, further comprising an anti-oxidation layer on a side of the first wiring layer away from the flexible substrate, wherein a material of the anti-oxidation layer comprises a gold nickel alloy, at least one pin comprises a first sub-pin in the first wiring layer and a second sub-pin in the anti-oxidation layer, and for a same pin, the second sub-pin covers the first sub-pin.

9. The chip on film of claim 8, wherein in the first direction, a thickness of the second sub-pin is greater than a thickness of the first sub-pin covered by the second sub-pin.

10. The chip on film of claim 1, further comprising a first height adjustment layer between the first wiring layer and the first insulation layer, wherein at least one pin comprises a first pin in the first wiring layer and a first height adjustment portion in the first height adjustment layer, and for a same pin, an orthographic projection of the first pin on the flexible substrate falls within an orthographic projection of the first height adjustment portion on the flexible substrate.

11. The chip on film of claim 10, wherein a material of the first height adjustment layer is different from a material of the first insulation layer, and the material of the first height adjustment layer is different from a material of the first wiring layer;
wherein a thickness of the first height adjustment portion in the first direction is more than 2 μm.

12. The chip on film of claim 1, further comprising: a first height adjustment layer on a side of the first wiring layer away from the flexible substrate;
and a second height adjustment layer on a side of the first height adjustment layer away from the flexible substrate,
wherein at least one pin comprises: a first pin in the first wiring layer; a first height adjustment portion in the first height adjustment layer; and a second height adjustment portion in the second height adjustment layer, wherein for a same pin, an orthographic projection of the second height adjustment portion on the flexible substrate falls within an orthographic projection of the first height adjustment portion on the flexible substrate, and the orthographic projection of the first height adjustment portion on the flexible substrate falls within an orthographic projection of the first pin on the flexible substrate.

13. The chip on film of claim 12, wherein a material of the first height adjustment layer is different from a material of the first wiring layer, and the material of the first height adjustment layer is different from a material of the second height adjustment layer;
wherein the second height adjustment layer comprises a conductive material, and the second height adjustment portion is electrically connected to the first pin through a third via hole penetrating the first height adjustment portion;
wherein a thickness of the first height adjustment portion in the first direction is more than 2 μm; and/or, a thickness of the second height adjustment portion in the first direction is more than 2 μm.

14. The chip on film of claim 1, wherein each of the first conductive material and the second conductive material comprises copper;
wherein the first insulation layer comprises a first inorganic insulation layer and a first planarization layer, the first inorganic insulation layer is between the first wiring layer and the first planarization layer, and the first insulation surface is a surface of the first inorganic insulation layer away from the flexible substrate;
wherein orthographic projections of the plurality of pins on the flexible substrate are arranged in an array, and orthographic projections of part of the plurality of pins on the flexible substrate at least partially overlaps with an orthographic projection of the second wire leading portion on the flexible substrate.

15. The chip on film of claim 6, wherein each of the first conductive material, the second conductive material and the third conductive material comprises copper.

16. (canceled)

17. The chip on film of claim 4, wherein in the first direction, a thickness of the first wire is equal to a thickness of the second wire.

18. (canceled)

19. (canceled)

20. (canceled)

21. (canceled)

22. A display device, comprising a display panel, a circuit board, and the chip on film of claim 1,
wherein the display panel is electrically connected to the circuit board through the chip on film.

23. A method for manufacturing a chip on film, comprising:
forming a second wiring layer on a flexible substrate, wherein the second wiring layer comprises a second conductive material;
forming, by using a patterning process, a second wire and a second wire leading portion in the second wiring layer, wherein the second wire is electrically connected to the second wire leading portion;
forming a first insulation layer on a side of the second wiring layer away from the flexible substrate;
forming a plurality of first via holes in the first insulation layer;
forming a first wiring layer on a side of the first insulation layer away from the flexible substrate, wherein the first wiring layer comprises a first conductive material; and
forming a plurality of pins in the first wiring layer, so that more than one pin is electrically connected to the second wire leading portion through more than one first via hole, respectively,
wherein the chip on film further comprises an adhesive overflow space between at least two adjacent pins among the plurality of pins, the first insulation layer comprises a first insulation surface away from the flexible substrate, the first insulation surface comprises a first insulation surface portion and a second insulation surface portion, an orthographic projection of the first insulation surface portion on the flexible substrate at least partially overlaps with an orthographic projection of more than one pin on the flexible substrate, an orthographic projection of the second insulation surface portion on the flexible substrate at least partially overlaps with an orthographic projection of the adhesive overflow space on the flexible substrate, at least part of a surface of the more than one pin close to the flexible substrate is in contact with the first insulation surface portion, at least part of the second insulation surface portion serves as a bottom surface of the adhesive overflow space, and the first insulation surface portion and the second insulation surface portion are in a same plane.

24. The method of claim 23, wherein the first conductive material comprises copper, and
the forming a first wiring layer on a side of the first insulation layer away from the flexible substrate comprises: forming a copper seed layer on the side of the first insulation layer away from the flexible substrate; and electroplating a copper layer on a surface of the copper seed layer away from the flexible substrate, so as to form the first wiring layer comprising the copper seed layer and the copper layer;
wherein the forming a plurality of pins in the first wiring layer, comprises:
performing a patterning process on the first wiring layer comprising the copper seed layer and the copper layer to form a first sub-pin; and
performing an electroless nickel immersion gold process on the first sub-pin to form a second sub-pin covering the first sub-pin.

25. (canceled)

26. The method of claim 23, wherein before forming the first wiring layer, the method further comprises: forming a first height adjustment layer on a side of the first insulation layer away from the flexible substrate; and performing a patterning process on the first height adjustment layer to form a first height adjustment portion in the first height adjustment layer; and
the forming a plurality of pins in the first wiring layer comprises: performing a dry etching process on the first wiring layer to form a first pin, so that at least one of the plurality of pins comprises the first pin in the first wiring layer and the first height adjustment portion in the first height adjustment layer, wherein for a same pin, an orthographic projection of the first pin on the flexible substrate falls within an orthographic projection of the first height adjustment portion on the flexible substrate; or
wherein the forming a plurality of pins in the first wiring layer, comprises:
performing a dry etching process on the first wiring layer to form a first pin;
forming a first height adjustment layer on a side of the first pin away from the flexible substrate, and performing a patterning process on the first height adjustment layer, so as to form a first height adjustment portion and a third via hole penetrating the first height adjustment portion; and
forming a second height adjustment layer on a side of the first height adjustment portion away from the flexible substrate, and performing a patterning process on the second height adjustment layer, so as to form a second height adjustment portion,
wherein for a same pin, an orthographic projection of the second height adjustment portion on the flexible substrate falls within an orthographic projection of the first height adjustment portion on the flexible substrate, and the orthographic projection of the first height adjustment portion on the flexible substrate falls within an orthographic projection of the first pin on the flexible substrate.

27. (canceled)
